(19) United States
(12) Patent Application Publication
(10) Pub. No.: US 2012/0112223 A1
(43) Pub. Date: May 10, 2012

(54) LED PACKAGE

(75) Inventor: TE-WEN KUO, Hukou (TW)

(73) Assignee: ADVANCED OPTOELECTRONIC TECHNOLOGY, INC., Hsinchu Hsien (TW)

(21) Appl. No.: 13/221,931

(22) Filed: Aug. 31, 2011

(30) Foreign Application Priority Data
Nov. 8, 2010 (CN) 201010534966.5

(51) Int. Cl. H01L 33/58

(52) U.S. Cl. 257/98; 257/E33.067; 257/E33.059

(57) ABSTRACT

An LED package includes a substrate, an LED chip, a transparent thermal insulation layer and an encapsulation including phosphor. The LED chip is arranged on the substrate and electrically connected to the substrate. The transparent thermal insulation layer is located between the LED package and the package layer whereby the phosphor is not affected by a high temperature generated by the LED chip when the LED chip is activated to generate light.

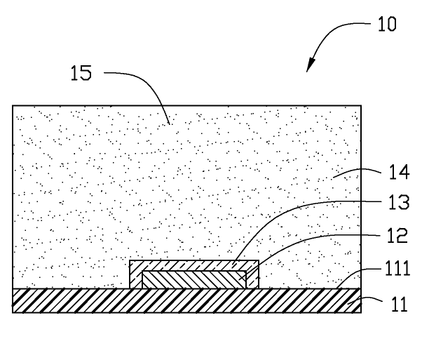

### BACKGROUND

1. Technical Field

The disclosure relates to light emitting diodes, and particularly to an LED package.

2. Description of the Related Art

Light emitting diodes (LEDs) have many advantages, such as high luminosity, low operational voltage, low power consumption, compatibility with integrated circuits, easy driving, long term reliability, and environmental friendliness. These advantages have promoted LEDs for wide use as a light source. Now, light emitting diodes are commonly applied in environmental lighting.

Light from common LED chips transfers to specific wavelengths by phosphor powders. However, phosphor powders are affected by a high temperature. Thus, an intensity of the light decreases due to high temperature.

Therefore, it is desirable to provide an LED package which can overcome the described limitations.

### BRIEF DESCRIPTION OF THE DRAWINGS

Many aspects of the disclosure can be better understood with reference to the only drawing. The components in the only drawing are not necessarily drawn to scale, the emphasis instead being placed upon clearly illustrating the principles of the present LED package.

The only FIGURE is a cross-sectional view of an LED package in accordance with a first embodiment.

### DETAILED DESCRIPTION

An embodiment of an LED package as disclosed is described in detail here with reference to the only drawing.

Referring to the only FIGURE, an LED package 10 includes a substrate 11, an LED chip 12, a transparent thermal insulation layer 13, and an encapsulation 14.

The substrate 11 includes a first surface 111. The substrate 11 supports the LED chip 12.

The LED chip 12 is arranged on the first surface 111 of the substrate 11. The LED chip 12 also can be fixed on the first surface 111 with glue. The LED chip 12 electrically connects to the substrate 11. The LED chip 12 also can be fixed on the substrate 11 by flip-chip or eutectic method. The LED chip 12 can be blue LED chip.

The transparent thermal insulation layer 13 covers on the LED chip 12. The transparent thermal insulation layer 13 is transparent thermal insulating materials. In this embodiment, the transparent thermal insulation layer 13 is a transparent aerogel material, such as SiO₂ aerogel, or TiO₂ aerogel. The transparent aerogel materials have excellent thermal insulating effect. The transparent thermal insulation layer 13 can efficiently resist heat from the LED chip 12. A thickness of the transparent thermal insulation layer 13 is 1-20 micrometer.

The encapsulation 14 encapsulates the transparent thermal insulation layer 13. The encapsulation 14 avoids the dust and vapor from damaging the LED chip 12. The encapsulation 14 can be silicone, epoxy, or other combinations. The encapsulation 14 further includes a plurality of phosphor powders 15. When the phosphor powders 15 are excited by energy, light with a specific color emits according to needs. The phosphor powders 15 can be garnet, sulfide, phosphide, nitride, nitrogen oxides, silicate, arsenide, selenium compounds, or telluride compounds.

The transparent thermal insulation layer 13 is between the LED chip 12 and the encapsulation 14. The transparent thermal insulation layer 13 has excellent thermal insulating effect. Most of heat form the LED chip 12 is efficiently resisted by the transparent thermal insulation layer 13. Thus, the phosphor powders 15 are not affected by a high temperature generated by the LED chip 12 when the LED chip 12 is activated to generate light.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An LED package, comprising: a substrate, an LED chip arranged on the substrate and electrically connecting to the substrate, a transparent thermal insulation layer, and an encapsulation having a plurality of phosphor powders, the transparent thermal insulation layer being arranged between the LED chip and the encapsulation whereby the phosphor powders are not affected by a high temperature generated by the LED chip when the LED chip is activated to generate light.

2. The LED package of claim 1, wherein the transparent thermal insulation layer is a transparent aerogel.

3. The LED package of claim 1, wherein the transparent thermal insulation layer is 1-20 micrometer.

4. The LED package of claim 2, wherein the transparent aerogel is SiO₂ aerogel, or TiO₂ aerogel.

5. The LED package of claim 1, wherein the transparent thermal insulation layer is arranged on the LED chip.

6. The LED package of claim 5, wherein the encapsulation is arranged on the transparent thermal insulation layer.

7. The LED package of claim 2, wherein the LED chip is a blue LED chip.

8. The LED package of claim 1, wherein the LED chip connects to the substrate by flip-chip or eutectic method.

9. The LED package of claim 1, wherein the encapsulation is silicone or epoxy.

10. The LED package of claim 1, wherein the phosphor powders are garnet, sulfide, phosphide, nitride, nitrogen oxides, silicate, arsenide, selenium compounds, or telluride compounds.
